(19) United States
(12) Patent Application Publication
(10) Pub. No.: US 2008/0160432 A1
(43) Pub. Date: Jul. 3, 2008

(54) Green Photosensitive Resin Composition and Color Filter Prepared Therefrom

(75) Inventors: Noh Seok BYON, Seoul (KR); Ju Ho JUNG, Seoul (KR); Gyu Seok HAN, Suwon-si (KR); Cheon Seok LEE, Seongnam-si (KR)

Correspondence Address: SUMMA, ALLAN & ADDITON, P.A., 11610 NORTH COMMUNITY HOUSE ROAD, SUITE 200, CHARLOTTE, NC, 28277, US

(73) Assignee: Cheil Industries Inc., Gumi-si (KR)

(21) Appl. No.: 11/949,114

(22) Filed: Dec. 3, 2007

(30) Foreign Application Priority Data
Dec. 28, 2006 (KR) 10-2006-0136211

(51) Int. Cl. G03F 3/00

(52) U.S. Cl. 430/7; 522/75

(57) ABSTRACT

The present invention relates to a photosensitive resin composition and a color filter prepared therefrom, and more particularly to a photosensitive resin composition comprising a zinc-containing, phthalocyanine-based green pigment with superior brightness improvement effect and a color filter prepared therefrom. The photosensitive resin composition of the present invention provides improved developability and chemical resistance, together with outstanding improved brightness.

### CROSS-REFERENCE TO RELATED PATENT APPLICATION

This non-provisional application claims priority under U.S.C. § 119(a) to Korean Patent Application No. 2006-136211, filed on Dec. 28, 2006, the entire contents of which are hereby incorporated by reference.

### FIELD OF THE INVENTION

The present invention relates to a photosensitive resin composition and a color filter prepared using the same.

### BACKGROUND OF THE INVENTION

Liquid crystal displays (LCDs), plasma display panels (PDPs), organic light-emitting diodes (OLEDs), and the like are used as electronic display devices in office automation equipment, portable compact televisions, video camera viewfinders, and so forth. Research directed to such products and techniques for the production of the same is actively underway.

Among the display devices, liquid crystal displays are used in notebook computers, monitors and TV screens because they are lightweight, thin and inexpensive, consume less power and are highly compatible with integrated circuits. A liquid crystal display device comprises a lower substrate including a black matrix, a color filter and an ITO pixel electrode and an upper substrate including an active circuit portion having a liquid crystal layer, a thin film transistor and a capacitor layer and an ITO pixel electrode.

A color filter is formed of a black matrix layer which is patterned on a transparent substrate in order to shield light at the interface between pixels and a pixel portion in which multiple colors (commonly, the three primary colors of red (R), green (G) and blue (B)) for constructing each pixel are aligned in a predetermined order. Such a color filter is prepared by coating pigments of at least three colors on a transparent substrate using various methods, such as dyeing, printing, electroplating, pigment dispersion, and the like.

In the dyeing method, a pattern of a dyeing base material, which is made of a natural photosensitive resin such as gelatin, and the like, or a synthetic resin such as amine modified polyvinyl alcohol, amine modified acryl, and the like, is formed on a substrate and dyeing is performed directly to obtain a colored film. The dyeing method, however, requires complicated steps and long processing times when there is a need to form a multi-color film on a single substrate, because an anti-dyeing treatment is needed for each color. Further, although the technique provides good clarity and dispersibility, in general, light resistance, moisture resistance and, most importantly, heat resistance are poor.

In the printing method, a colored film is formed by printing a pigment-dispersed ink on a heat-curing or light-curing resin and then curing it with heat or light. This method is advantageous over other methods in terms of cost, but it is difficult to obtain ultrafine and delicate image qualities. Further, the resultant film tends to be non-uniform.

Another method is the electroplating technique using electrodeposition. This technique offers fine color pattern and provides superior heat resistance and light resistance because a pigment is used. However, as the pixel size becomes smaller and the electrode pattern becomes more delicate, color staining occurring at both ends caused by electrical resistance or large color film thickness makes it inapplicable to high-precision color filters.

The pigment dispersion technique is a method of forming a colored film by repeating the steps of coating, light exposure, development and heat curing of a photopolymerizable composition comprising a coloring agent on a transparent substrate provided with a black matrix. The pigment dispersion technique is advantageous in that heat resistance, which is the most important feature for a color filter, and durability can be improved and the film thickness can be uniformly maintained.

Typically, a photosensitive resin composition used to prepare a color filter by pigment dispersion comprises a binder resin, a photopolymerizable monomer, a photopolymerization initiator, an epoxy resin, a solvent, and an additive, among other components.

A wide color gamut and high transmittance are required to improve the performance of a liquid crystal display. When a high concentration of a pigment is used to widen the color gamut of the thin film transistor of a liquid crystal display, brightness is sacrificed. Accordingly, the development of red, blue and green photosensitive resin compositions having superior color gamut and improved brightness as compared to that of conventional photosensitive resin compositions, that is, ones having superior brightness to that of conventional photosensitive resin compositions, is required.

Currently, C. I. (color index) pigment green 7 (hereinafter PG7) made of a chlorinated copper phthalocyanine pigment and C. I. pigment green 36 (hereinafter PG36) made of a brominated copper phthalocyanine pigment are generally used as the green pigment in the green pixels of a color filter. Although PG7 has a strong color strength, it has too strong a bluish tinge, so that a large amount of yellow needs to be mixed to provide a green color for the pixels meeting sRGB, NTSC and EBU specifications. Furthermore, since it has a low transmittance, a dark color filter is provided if the green pixels are formed mainly with PG7.

In contrast, PG36 shows a relatively yellowish spectral transmittance spectrum and a wide half bandwidth with a wide spectral transmittance width in the vicinity of the peak top so as to transmit the bright line in the sub-wavelength range. Thus PG36 shows an extremely high transmittance. However, PG36 has a low color strength. Therefore, in order to form the green pixels for displaying a range with a high color strength (high density region) on the color coordinates, the PG36 pigment has to be used in large amounts, which reduces the pixel transmittance. Even though the concentration of yellow pigment can be increased to offset the color coordinates to the yellow direction to ensure high transmittance, such methods require a large amount of yellow pigment, which increases the total amount of pigment used. Therefore, there is a need for a photosensitive resin composition comprising a pigment capable of replacing conventional halogenated copper phthalocyanine pigments such as PG7 and PG36 for forming the green pixels of a color filter.

### SUMMARY OF THE INVENTION

One aspect of the present invention is a photosensitive resin composition comprising a zinc-containing green pigment. The photosensitive resin composition of the invention is capable of improving the brightness of a color filter and is also capable of forming a color filter having a wide color gamut and a high transmittance.

In accordance with this aspect of the invention, the photosensitive resin composition can include:

about 1 to about 40 wt % of a zinc-containing, phthalocyanine-based green pigment;

about 0.1 to about 30 wt % of an acryl based binder resin having a carboxyl group;

about 0.1 to about 10 wt % of an epoxy resin;

about 0.5 to about 30 wt % of a photopolymerizable monomer;

about 0.1 to about 10 wt % of a photopolymerization initiator; and

a solvent as the remainder.

In another aspect, the present invention provides a color filter comprising a pattern formed using the photosensitive resin composition of the present invention and a liquid crystal display comprising the same. The color filter of the invention can exhibit improved brightness, developability, chemical resistance and color gamut.

### BRIEF DESCRIPTION OF THE DRAWINGS

FIG. 1 shows the x and y values in the CIE chromaticity diagram of the color filters prepared in Example 1 and Comparative Example 1.

FIG. 2 shows the x and Y (brightness) values in the CIE chromaticity diagram of the color filters prepared in Example 1 and Comparative Example 1.

FIG. 3 shows the wavelength-dependent light transmittance of the color filter prepared in Example 1 and Comparative Example 1.

### DETAILED DESCRIPTION OF THE INVENTION

The present invention now will be described more fully hereinafter in the following detailed description of the invention, in which some, but not all embodiments of the invention are described. Indeed, this invention may be embodied in many different forms and should not be construed as limited to the embodiments set forth herein; rather, these embodiments are provided so that this disclosure will satisfy applicable legal requirements.

The photosensitive resin composition of the present invention employs a zinc-containing, phthalocyanine-based green pigment as a coloring agent, instead of the conventional copper phthalocyanine pigment used for green color, in order to improve brightness.

The zinc-containing, phthalocyanine-based green pigment that can be used in the present invention may have the following formula (1):

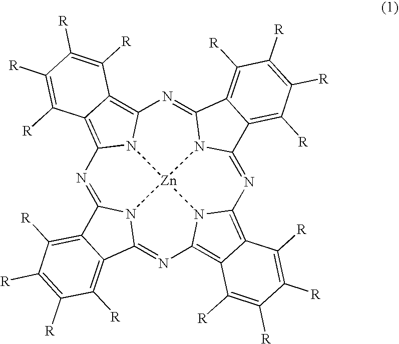

in which each R is identical or different and is independently selected from the group consisting of Cl, Br, H, F and OH.

The photosensitive resin composition of the invention can include the zinc-containing, phthalocyanine-based green pigment in an amount of about 1 to about 40 wt %, for example about 5 to about 20 wt %, based on the total weight of the composition. If the amount of the zinc-containing, phthalocyanine-based green pigment is below about 1 wt %, the composition may not provide the desired color gamut. If the amount of the zinc-containing phthalocyanine-based green pigment exceeds about 40 wt %, however, the composition may not exhibit desired curing performance and adhesion properties.

In addition to the zinc-containing, phthalocyanine-based green pigment, the photosensitive resin composition of the present invention may further comprise a yellow pigment or a copper phthalocyanine based green pigment. In such a case, an improved brightness (Y) can be attained as compared to the brightness of a composition in which the copper phthalocyanine based pigment is used alone or the copper phthalocyanine based pigment is used together with a yellow pigment. Non-limiting examples of such yellow pigments or copper phthalocyanine based green pigments include a chlorinated copper phthalocyanine green pigment, C. I. pigment yellow 138, C. I. pigment yellow 150 and a combination thereof.

The copper phthalocyanine based green pigment, chlorinated copper phthalocyanine based green pigment, C. I. pigment yellow 138 or C. I. pigment yellow 150 may be used separately or in combination in an amount of about 1 to about 150 wt % per 100 wt % of the zinc-containing, phthalocyanine-based green pigment, and within about 40 wt % of the photosensitive resin composition.

The acryl based binder resin having a carboxyl group used in the present invention is a copolymer of an ethylenic unsaturated monomer having one or more carboxyl groups and one or more of another ethylenic unsaturated monomer copolymerizable with the same. The content of the ethylenic unsaturated monomer having a carboxyl group can be about 5 to about 50%, for example about 10 to about 40 wt %, of the entire copolymer. The acryl based binder resin having a carboxyl group can have a molecular weight (M_{w}) in the range of about 3,000 to about 150,000, for example, about 5,000 to about 50,000.

Further, the acryl based binder resin having a carboxyl group may have an acid value in the range of about 20 to about 50 mg/KOH. Examples of the ethylenic unsaturated monomer having a carboxyl group include ones selected from the group consisting of acrylic acid, methacrylic acid, maleic acid, itaconic acid, fumaric acid and mixtures thereof.

Non-limiting examples of the other ethylenic unsaturated monomer copolymerizable with the ethylenic unsaturated monomer having a carboxyl group include unsaturated carboxylic acid esters such as styrene, α-methylstyrene, vinyltoluene, vinylbenzyl methyl ether, methyl acrylate, methyl methacrylate, ethyl acrylate, ethyl methacrylate, butyl acrylate, butyl methacrylate, 2-hydroxyethyl acrylate, 2-hydroxyethyl methacrylate, 2-hydroxybutyl acrylate, 2-hydroxybutyl methacrylate, benzyl acrylate, benzyl methacrylate, cyclohexyl acrylate, cyclohexyl methacrylate, phenyl acrylate, phenyl methacrylate, and the like; unsaturated carboxylic acid aminoalkyl esters such as 2-aminoethyl acrylate, 2-aminoethyl methacrylate, 2-dimethylaminoethyl acrylate, 2-dimethylaminoethyl methacrylate, etc.; carboxylic acid vinyl esters such as vinyl acetate, vinyl benzoate, and the like; unsaturated carboxylic acid glycidyl esters such as glycidyl acrylate, glycidyl methacrylate, and the like; vinyl cyanide compounds such as acrylonitrile, methacrylonitrile, and the like; unsaturated amides such as acrylamide, methacrylamide, and the like; and mixtures thereof.

Specific examples of the acryl based binder resin having a carboxyl group comprising said monomers include a methacrylic acid/benzyl methacrylate copolymer, a methacrylic acid/benzyl methacrylate/2-hydroxyethyl methacrylate copolymer, a methacrylic acid/benzyl methacrylate/styrene/2-hydroxyethyl methacrylate copolymer, and the like.

The photosensitive resin composition of the invention can include the acryl based binder resin having a carboxyl group in an amount of about 0.1 to about 30 wt %, based on the total weight of the composition. If the amount of the acryl based binder resin having a carboxyl group is below about 0.1 wt %, it can be difficult to develop the composition using an alkaline developing solution. If the content of the acryl based binder resin exceeds about 30 wt %, however, surface roughness may increase due to the lack of crosslinkability.

The photopolymerizable monomer used in the present invention may be a monomer commonly used in photosensitive resin compositions for a color filter. Non-limiting examples include ethylene glycol diacrylate, triethylene glycol diacrylate, 1-4-butanediol diacrylate, 1,6-hexanediol diacrylate, neopentylglycol diacrylate, pentaerythritol diacrylate, pentaerythritol triacrylate, dipentaerythritol diacrylate, dipentaerythritol triacrylate, dipentaerythritol pentaacrylate, pentaerythritol hexaacrylate, bisphenol A diacrylate, trimethylolpropane triacrylate, novolac epoxy acrylate, ethylene glycol dimethacrylate, diethylene glycol dimethacrylate, triethylene glycol dimethacrylate, propylene glycol dimethacrylate, 1,4-butanediol dimethacrylate, 1,6-hexanediol dimethacrylate, and the like, and mixtures thereof.

The photosensitive resin composition of the invention can include the photopolymerizable monomer in an amount of about 0.5 to about 30 wt %, based on the total weight of the composition. If the amount of the photopolymerizable monomer is below about 0.5 wt % of the entire composition, the edge of the cured film may be unclear due to excessive developing. If the amount of the photopolymerizable monomer exceeds about 30 wt %, however, it can be difficult to develop the composition using an alkaline developing solution.

Further, in the present invention, at least one modified monomer of glycerol triacrylate represented by the following formula (2) may be used as the photopolymerizable monomer in order to improve curing performance and developability:

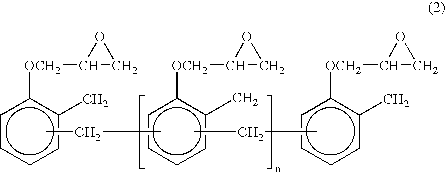

in which each of l, m and n is an integer 1 or larger and l+m+n ranges from 3 to 10.

The photosensitive resin composition of the invention can include the modified monomer of glycerol triacrylate in an amount of about 0.5 to about 10 wt %, based on the total weight of the composition.

The photopolymerization initiator used in the present invention may be a photopolymerization initiator commonly used in photosensitive resin compositions. For example, an acetophenone based compound, a benzophenone based compound, a thioxanthone based compound, a benzoin based compound, a triazine based compound, an oxime based compound, and the like, and mixtures thereof, may be used.

Non-limiting, specific examples of the acetophenone based compound that can be used as the photopolymerization initiator include 2,2′-diethoxyacetophenone, 2,2′-dibutoxyacetophenone, 2-hydroxy-2-methylpropiophenone, p-t-butyltrichloroacetophenone, p-t-butyldichloroacetophenone, benzophenone, 4-chloroacetophenone, 4,4′-dichlorobenzophenone, 3,3′-dimethyl-2-methoxybenzophenone, 2,2′-dichloro-4-phenoxyacetophenone, 2-methyl-1-(4-(methylthio)phenyl)-2-morpholinopropan-1-one, 2-benzyl-2-dimethylamino-1-(4-morpholinophenyl)-butan-1-one, and the like, and mixtures thereof.

Non-limiting examples of the benzophenone based compound include benzophenone, benzoyl benzoate, benzoylmethyl benzoate, 4-phenylbenzophenone, hydroxybenzophenone, acrylated benzophenone, 4,4′-bis(dimethylamino)benzophenone, 4,4′-bis(diethylamino)benzophenone, and the like, and mixtures thereof. Non-limiting examples of the thioxanthone based compound include thioxanthone, 2-chlorothioxanthone, 2-methylthioxanthone, isopropylthioxanthone, 2,4-diethylthioxanthone, 2,4-isopropylthioxanthone, 2-chlorothioxanthone, and the like, and mixtures thereof.

Non-limiting examples of the benzoin based compound include benzoin, benzoin methyl ether, benzoin ethyl ether, benzoin isopropyl ether, benzoin isobutyl ether, benzyl dimethyl ketal, and the like, and mixtures thereof.

Non-limiting examples of the triazine based compound include 2,4,6-trichloro-s-triazine, 2-phenyl-4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tryl)-4,6-bis(trichloromethyl)-s-triazine, 2-biphenyl-4,6-bis(trichloromethyl)-s-triazine, bis(trichloromethyl)-6-styryl-s-triazine, 2-(naphtho-1-yl)-4,6-bis(trichloromethyl)-s-triazine, 2-(4-methoxy-1-yl)4,6-bis(trichloromethyl)-s-triazine, 2,4-trichloromethyl(piperonyl)-s-triazine, 2,4-trichloromethyl(4′-methoxystyryl)-s-triazine, and the like, and mixtures thereof. In the present invention, in addition to the above-mentioned photopolymerization initiators, commercially available photopolymerization initiators such as carbazole based compounds, diketone compounds, sulfonium borate based compounds, diazo based compounds, diimidazole based compounds, and the like, and mixtures thereof, may also be used.

The photosensitive resin composition of the invention can include the photopolymerization initiator in an amount of about 0.1 to about 10 wt %, based on the total weight of the composition. If the amount of the photopolymerization initiator is below about 0.1 wt %, photopolymerization may not proceed sufficiently during light exposure. If the amount of the photopolymerization initiator exceeds about 10 wt %, however, unreacted initiator remaining after photopolymerization may reduce transmittance.

In the present invention, a water-soluble organic solvent such as diethylene glycol, glycerin, ethylene glycol, propylene glycol, polyethylene glycol, polypropylene glycol, 2-(methoxymethoxy)ethanol, 2-butoxyethanol, 2-(isopentyloxy)ethanol, 2-(hexyloxy)ethanol, diethylene glycol monomethyl ether, diethylene glycol monoethyl ether, diethylene glycol monobutyl ether, triethylene glycol, triethylene glycol monomethyl ether, 1-methoxy-2-propanol, 1-ethoxy-2-propanol, dipropylene glycol, dipropylene glycol monomethyl ether, dipropylene glycol monomethyl ether, dipropylene glycol, and the like, and mixtures thereof may be used as solvent. The amount of the organic solvent is not particularly limited.

Also, in the present invention, the photosensitive resin composition of the invention can include an epoxy resin to improve crosslinkability, heat resistance, chemical resistance, and the like of the patterned film when preparing a color filter using the composition of the present invention.

The epoxy resin useful for the present invention may be any one having good reactivity and superior heat resistance and chemical resistance. Exemplary thermosetting epoxy resins useful in the present invention can include without limitation at least one epoxy resin selected from bisphenol A-epoxy resin, novolac type epoxy resin, brominated epoxy resin, fatty acid epoxy resin, and the like, and mixtures thereof. An exemplary epoxy resin useful in the present invention is o-cresol novolac epoxy resin.

The photosensitive resin composition of the invention can include the epoxy resin in an amount of about 0.1 to about 10 wt %. If the amount of the epoxy resin is below about 0.1 wt %, the film's crosslinkability is not improved and the improvement of chemical resistance may be minimal. If the amount of the epoxy resin exceeds about 10 wt %, however, the composition tends to adhere to the glass plate during soft baking, resulting in reduced developability and increased residuals.

In addition to the aforesaid components, the photosensitive resin composition of the present invention may further comprise such additives as surfactant, dispersant, coupling agent, and the like, and mixtures thereof, in amounts suitable for use in such compositions and not affecting the physical properties of the composition.

The photosensitive resin composition of the invention can include, for example, at least one dispersant selected from the group consisting of polyester based dispersants, polyethyleneimine based dispersants, polyurethane based dispersants, acrylic acid based dispersants, and the like, and mixtures thereof, in an amount of about 0.001 to about 100 wt %, based on the total weight (per 100 wt %) of the pigment.

The photosensitive resin composition of the invention can include as the coupling agent a silane based compound having at least one functional group selected from vinyl, epoxy, methacryloxy, acryloxy and amino groups, in an amount of about 0.01 to about 1 wt %, based on the total weight of the composition, in order to improve crosslinkability and adhesion.

Further, in the present invention, a surfactant may be used to disperse the pigment component uniformly in the solvent and improve leveling property. Exemplary surfactants include fluorine based surfactants. The fluorine based surfactant not only provides superior electrical property but also provides superior leveling property during high speed coating, reduces foam generation and film defects. Consequently, it is valuable in slit coating, one of the high speed coating techniques. A polyether co-modified silicone may be used as the fluorine based surfactant. Non-limiting, specific examples include FC-430 and F-475, commercially available from 3M. They may be used either alone or in combination. The photosensitive resin composition of the invention can include the fluorine based surfactant in an amount of about 0.01 to about 5 wt %, based on the total weight of the composition. If the surfactant is used in an amount outside this range, the problem of impurity generation after developing may occur.

The photosensitive resin composition of the present invention can be prepared using any suitable method in the art useful for the production of such a composition. It may be prepared, for example, by mixing a zinc-containing, phthalocyanine-based green pigment, an acryl based binder resin having a carboxyl group, an epoxy resin, a photopolymerizable monomer and a photopolymerization initiator with a solvent.

In another aspect, the present invention provides a color filter patterned using the photosensitive resin composition of the present invention and a liquid crystal display comprising the color filter. The color filter of the present invention can have a transmittance of about 90 to about 100 at a wavelength ranging from about 500 nm to about 570 nm.

The color filter of the present invention can be manufactured using any suitable method in the art useful for producing a color filter. One exemplary non-limiting method of preparing a color filter for a liquid crystal display using the photosensitive resin composition of the present invention is described below.

A zinc-containing, phthalocyanine-based green pigment, an acryl based binder resin having a carboxyl group, an epoxy resin, a photopolymerizable monomer and a photopolymerization initiator are mixed and diluted appropriately using a solvent to obtain a photosensitive resin composition. Subsequently, the composition is coated on a substrate (e.g., glass substrate) using any suitable technique such as spin coating, roller coating, spray coating, and the like, to a thickness of, for example, about 0.5 to about 10 μm and then dried to obtain a film.

Then, light illumination is performed after placing a photomask with a pattern for the color filter on the film. The light source may be UV in the wavelength region, for example, from 190 nm to 450 nm, for example, from 200 nm to 400 nm. Electron beam or X-ray also may be used. After illumination, the coating layer is treated with a developing solution. Then, the unexposed part of the coating layer is removed and the desired pattern is obtained. This process can be repeated depending on the number of desired colors in order to obtain a color pattern with a wanted pattern. The obtained image pattern may be further heated or cured by exposing to light. The resultant color filter of the present invention can have improved properties such as heat resistance, light resistance, adhesion, crack resistance, chemical resistance, strength, pattern gradient, storage stability, and the like.

The following examples describe various exemplary embodiments of the present invention. Other embodiments will be apparent to those skilled in the art from consideration of the specification or practice of the invention as disclosed herein. It is intended that the specification, together with the examples, be considered exemplary only, with the scope and spirit of the invention being indicated by the claims, which follow the examples.

### EXAMPLES 1 AND 2

A photosensitive resin composition is prepared using the components listed in Table 1 below.

Photopolymerization initiators [TAZ-110 (Midori Chemical), Irgacure 907 (Ciba-Geigy), 4,4′-bis(diethylamino)benzophenone (Hodogaya Chemical)] and an o-cresol novolac epoxy resin are dissolved in a propylene glycol monomethyl ether solvent and stirred at room temperature for 2 hours. Subsequently, an acryl based binder resin having a carboxyl group (methacrylic acid/benzyl methacrylate=30:70 (w/v), molecular weight (M_{w})=20,000), dipentaerythritol hexaacrylate, as photopolymerizable monomer, and trimethylolpropane polypropoxylate triacrylate, a modified monomer of glycerol triacrylate, are added and stirring is performed at room temperature for 2 hours. Next, a brominated zinc phthalocyanine green pigment (DIC) is added and stirring is performed at room temperature for 1 hour. Subsequently, a methacryloxy silane coupling agent (Chisso) and a fluorine based surfactant (F-475, DIC) are added and stirring is performed at room temperature for 1 hour. The resultant solution is filtered 3 times to remove impurities.

The photosensitive resin composition is coated on an oil-free cleaned 1 mm-thick glass substrate to a thickness of 1 to 2 μm and dried at 80° C. for 2 minutes on a hot plate to obtain a film. A photomask is placed on the film and light exposure is performed at a wavelength of 365 nm using a high pressure mercury lamp. Then, developing is performed for 60 seconds at 30° C. under normal pressure, using a 1% potassium hydroxide aqueous solution. After developing, the glass plate is dried in a convection oven at 220° C. for 40 minutes to obtain the wanted pattern. Brightness improvement, developability and chemical resistance are evaluated for the obtained pattern. The results are given in Table 2 below.

TABLE 1

| | | | Comp. | Comp. | Comp. |
|---|---|---|---|---|---|
| Components (unit: g) | Ex. 1 | Ex. 2 | Ex. 1 | Ex. 2 | Ex. 3 |
| Brominated zinc phthalocyanine green | 7 | 7 | — | 7 | 7 |
| pigment | | | | | |
| Copper phthalocyanine based green | — | — | 7 | — | — |
| pigment | | | | | |
| Acryl based binder resin having carboxyl group | 15 | 15 | 15 | 16.3 | 15.3 |
| Dipentaerythritol hexaacrylate | 4 | 4 | 4 | 4 | 4 |
| Modified monomer of glycerol triacrylate | 1 | 1 | 1 | — | 1 |
| Photopolymerization initiator 1 (TAZ- | 0.5 | 0.5 | 0.5 | 0.5 | 0.5 |
| 110) | | | | | |
| Photopolymerization initiator 2 (Irgacure | 0.5 | 0.5 | 0.5 | 0.5 | 0.5 |
| 907) | | | | | |
| Photopolymerization initiator 3 (4,4′- | 0.5 | 0.5 | 0.5 | 0.5 | 0.5 |
| bis(diethylamino)benzophenone) | | | | | |
| Propylene glycol monomethyl ether o- | 71.2 | 70.8 | 70.8 | 70.8 | 70.8 |
| Cresol novolac epoxy resin | 0.3 | 0.3 | 0.3 | — | — |
| Methacryloxysilane coupling agent | — | 0.2 | — | 0.2 | 0.2 |
| Fluorine based surfactant | — | 0.2 | — | 0.2 | 0.2 |

### COMPARATIVE EXAMPLE 1

A photosensitive resin composition is prepared in the same manner as in Example 1, except that a copper phthalocyanine based green pigment (C. I. pigment green 36) is used instead of a brominated zinc phthalocyanine green pigment.

### COMPARATIVE EXAMPLE 2

A photosensitive resin composition is prepared in the same manner as in Example 2, except that a modified monomer of glycerol triacrylate and an o-cresol novolac epoxy resin are not used.

### COMPARATIVE EXAMPLE 3

A photosensitive resin composition is prepared in the same manner as in Example 2, except that an o-cresol novolac epoxy resin is not used.

TABLE 2

| | Brightness | | Chemical |
|---|---|---|---|
| | improvement | Developability | resistance |
| Example 1 | ∘ | ∘ | ∘ |
| Comparative Example 1 | X | ∘ | Δ |
| Comparative Example 2 | ∘ | Δ | x |
| Comparative Example 3 | ∘ | ∘ | x |

### [Evaluation of Physical Properties]

### Brightness (Y) Improvement

The patterns obtained in Examples and Comparative Examples are evaluated using a color measurement instrument. CIE chromaticity values x, y and Y are obtained. Y values are compared for the same x and y values and evaluated according to the following standard:

∘: Superior brightness improvement (Y≧73.5 for the same x and y and Gy=0.540);

Δ: Good brightness improvement (72.5≦Y≦73.5 for the same x and y and Gy=0.540); and

x: Poor brightness improvement (Y<72.5 for the same x and y and Gy=0.540).

### Developability

The patterns obtained in Examples and Comparative Examples are examined for the presence of residuals with naked eyes under a halogen lamp. The patterns are evaluated based on the developing time and the presence of residuals, according to the following standard:

∘: Superior developability (developing time=15-25 seconds, no residuals);

Δ: Good developability (developing time=26-35 seconds, no residuals); and

x: Poor developability (developing time=36 seconds or longer, residuals remain on the pattern).

### Chemical Resistance

The patterns obtained in Examples and Comparative Examples are immersed in 5% hydrochloric acid solution, 5% sodium hydroxide solution, N-methylpyrrolidone (NMP), xylene and isopropyl alcohol (IPA) for 30 minutes. After drying, the patterns are observed with an optical microscope. Also, del(E*) before and after the experiment is measured using a color measurement instrument. The patterns are evaluated according to the following standard:

∘: Superior chemical resistance (no pattern change, del(E*)<3.0);

Δ: Good chemical resistance (slight pattern change, 3.0≦del(E*)<5.0); and

x: Poor chemical resistance (noticeable pattern change, del(E*)≧5.0).

### Comparison of Brightness Improvement

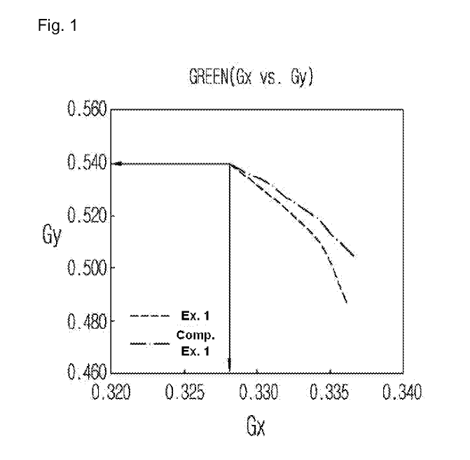

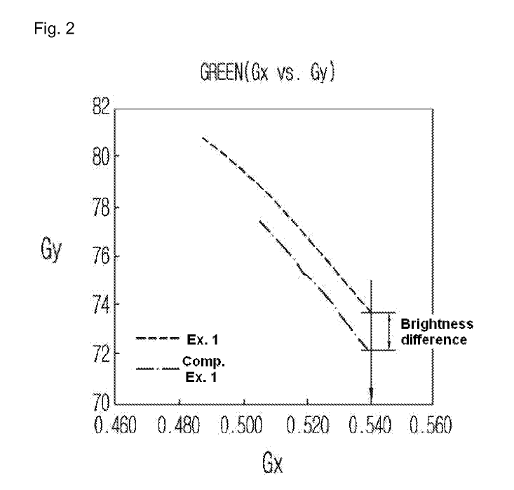

Brightness improvement is compared for the patterns obtained in Example 1 and Comparative Example 1, using a color measurement instrument. FIG. 1 shows the x and y values in the CIE chromaticity diagram of the color filters prepared in Example 1 and Comparative Example 1. And, FIG. 2 shows the x and Y (brightness) values in the CIE chromaticity diagram of the color filters prepared in Example 1 and Comparative Example 1.

In FIG. 1, the same CIE coordinate values x=0.328 and y=0.540 indicate that the two colors are identical. In FIG. 2, for the same y=0.540, the Y value (brightness) for Example 1 is 73.7, whereas that of Comparative Example 1 is 72.1 (i.e., improved by 1.6). This means that Example 1 offers better brightness than Comparative Example 1.

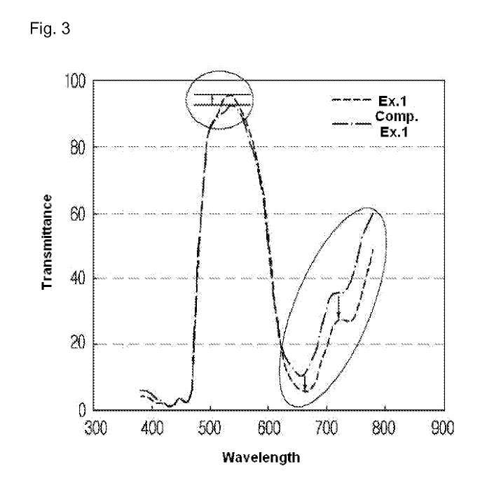

FIG. 3 shows this result in terms of transmittance. Around 535 nm, the transmittance of Example 1 is higher than that of Comparative Example 1, while the transmittance of Example 1 is lower than that of Comparative Example 1 at 615 nm or above. From this result, it can be confirmed that the color filter of the present invention offers outstandingly improved brightness for the same color because the color purity increases transmittance decreases at a specific wavelength.

The photosensitive resin composition for preparing a color filter according to the present invention provides brightness improvement and, thereby, improves developability and chemical resistance and offers improved processability and color gamut. Therefore, it can be used as the color filter for the high-quality liquid crystal display.

Many modifications and other embodiments of the invention will come to mind to one skilled in the art to which this invention pertains having the benefit of the teachings presented in the foregoing descriptions. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation, the scope of the invention being defined in the claims.

What is claimed is:

1. A photosensitive resin composition comprising:
about 1 to about 40 wt % of a zinc-containing, phthalocyanine-based green pigment;
about 0.1 to about 30 wt % of an acryl based binder resin having a carboxyl group;
about 0.1 to about 10 wt % of an epoxy resin;
about 0.5 to about 30 wt % of a photopolymerizable monomer;
about 0.1 to about 10 wt % of a photopolymerization initiator; and
a solvent as remainder.

2. The photosensitive resin composition as set forth in claim 1, wherein the zinc-containing, phthalocyanine-based green pigment has a structure represented by the following formula (1): 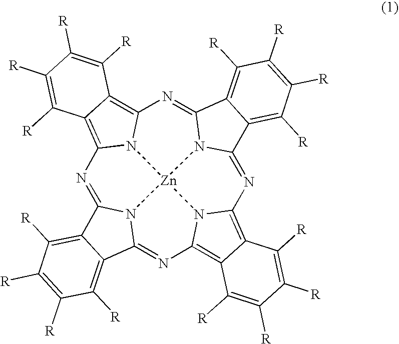
in which each R is independently selected from the group consisting of Cl, Br, H, F and OH.

3. The photosensitive resin composition as set forth in claim 1, comprising the zinc-containing, phthalocyanine-based green pigment in an amount of about 5 to about 20 wt %.

4. The photosensitive resin composition as set forth in claim 1, wherein said photopolymerizable monomer is a modified monomer of glycerol triacrylate represented by the following formula (2): 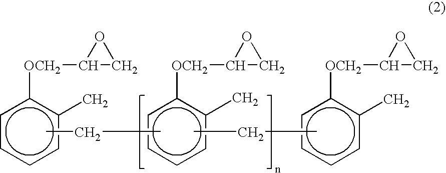
in which each of l, m and n is an integer 1 or larger and l+m+n ranges from 3 to 10.

5. The photosensitive resin composition as set forth in claim 4, comprising the modified monomer of glycerol triacrylate in an amount of about 0.5 to about 10 wt %.

6. The photosensitive resin composition as set forth in claim 1, wherein the composition further comprises at least one additional pigment selected from the group consisting of a copper phthalocyanine based green pigment, C. I. pigment yellow 138, C. I. pigment yellow 150, and mixtures thereof.

7. The photosensitive resin composition as set forth in claim 1, wherein the epoxy resin comprises at least one thermosetting epoxy resin selected from the group consisting of bisphenol A-ECH resin, novolac type epoxy resin, brominated epoxy resin, fatty acid epoxy resin, and mixtures thereof.

8. The photosensitive resin composition as set forth in claim 1, wherein the epoxy resin is an o-cresol novolac epoxy resin.

9. The photosensitive resin composition as set forth in claim 1, wherein the composition further comprises at least one dispersant selected from the group consisting of polyester based dispersants, polyethyleneimine based dispersants, polyurethane based dispersants, acrylic acid based dispersants, and mixtures thereof, in an amount of about 0.001 to about 100 wt % based on 100 wt % of the pigment.

10. The photosensitive resin composition as set forth in claim 1, wherein the composition further comprises a fluorine based surfactant in an amount of about 0.01 to about 5 wt %, based on the total weight of the composition.

11. A color filter comprising a pattern formed from a photosensitive resin composition comprising:
about 1 to about 40 wt % of a zinc-containing, phthalocyanine-based green pigment;
about 0.1 to about 30 wt % of an acryl based binder resin having a carboxyl group;
about 0.1 to about 10 wt % of an epoxy resin;
about 0.5 to about 30 wt % of a photopolymerizable monomer;
about 0.1 to about 10 wt % of a photopolymerization initiator; and
a solvent as remainder.

12. The color filter as set forth in claim 11, wherein the color filter has a transmittance of about 90 to about 100 in the wavelength range from about 500 nm to about 570 nm.

13. A color filter comprising a pattern formed of a photosensitive resin composition comprising a zinc-containing, phthalocyanine-based green pigment.

14. A liquid crystal display comprising a color filter comprising a pattern formed from a photosensitive resin composition comprising:
about 1 to about 40 wt % of a zinc-containing, phthalocyanine-based green pigment;
about 0.1 to about 30 wt % of an acryl based binder resin having a carboxyl group;
about 0.1 to about 10 wt % of an epoxy resin;
about 0.5 to about 30 wt % of a photopolymerizable monomer;
about 0.1 to about 10 wt % of a photopolymerization initiator; and
a solvent as remainder.

15. A liquid crystal display comprising a color filter comprising a pattern formed from a photosensitive resin composition comprising a zinc-containing, phthalocyanine-based green pigment.
